(19) United States
(12) Patent Application Publication
(10) Pub. No.: US 2022/0029073 A1
(43) Pub. Date: Jan. 27, 2022

(54) LIGHT EMITTING DIODE PACKAGE HAVING GLUE ON TWO SIDES

(71) Applicant: Blooming International Limited, British West Indies (AI)

(72) Inventor: Shu-Fa SHAO, Taipei (TW)

(21) Appl. No.: 17/153,066

(22) Filed: Jan. 20, 2021

(51) Int. Cl. H01L 33/54; H01L 25/075; H01L 33/60; H01L 33/62; H01L 33/64

(52) U.S. Cl. CPC H01L 33/54; H01L 25/0753; H01L 33/647; H01L 33/62; H01L 33/60

(57) ABSTRACT

A light emitting diode package includes a metal frame, an LED chip, and a transparent glue bulk. The metal frame includes a first mounting pad and second mounting pad. A light transmission gap is defined between the first mounting pad and the second mounting pad, and the light transmission gap communicates between a top and bottom surfaces of the metal frame and keeps the first and second mounting pads spaced from each other. The LED chip is mounted on the first mounting pad and corresponds to the top surface. A first and second electrodes of the LED chip are electrically connected to the first and the second mounting pads respectively. The transparent glue bulk covers the top and bottom surfaces, covers the LED chip, and fills the light transmission gap. Outer edges of the first and second mounting pad are exposed from the transparent glue bulk.

### CROSS-REFERENCE TO RELATED APPLICATIONS

The present application claims priority to Chinese Patent Application No. 202010722870.5, filed on Jul. 24, 2020, said application being incorporated by reference in its entirety herein.

### FIELD OF THE INVENTION

This disclosure relates to an optoelectronic device, and in particular, to a light emitting diode lamp package having glue on two sides.

### BACKGROUND

A light emitting diode is a solid-state optoelectronic device configured to transform electricity into luminous energy. The light emitting diode includes a semiconductor chip. A negative electrode of the chip is connected to a metal frame, the positive electrode of the chip is connected to a power supply pin, and the chip is completely wrapped by epoxy resins. The LED chip includes a P-type semiconductor and an N-type semiconductor. When current is applied to the chip via bonding wires, the chip illuminates. The LED chip requires protection from dust and dirt, humidity, electrostatic discharge (ESD) and mechanical disruption. When applying current, heat generated in the P-N semiconductors has to be removed to prevent the light emitting diode from being overheated. In the art various materials and package structures are developed to remove heat generated by the light emitting diode.

FIG. 1, FIG. 2, and FIG. 3 show a light emitting diode package 1 known in the art, in which FIG. 1 is a front view, FIG. 2 is a top view, and FIG. 3 is a bottom view. As shown in the drawings, the light emitting diode package includes a printed circuit board 2, an LED chip 3, a first bonding wire 4, a second bonding wire 5, and a transparent glue bulk 6. A chip bonding pad 2c and a wire bonding pad 2d are disposed on a top surface of the printed circuit board 2, and two mounting pads 2e are disposed on a bottom surface of the printed circuit board 2. The LED chip 3 is mounted on the chip bonding pad 2c. The first bonding wire 4 and the second bonding wire 5 respectively connect two electrodes of the LED chip to the chip bonding pad 2c and the wire bonding pad 2d. The transparent glue bulk 6, of epoxy resins or silicon, is molded to wrap the LED chip 3, the first bonding wire 4 and the second bonding wire 5, so as to protect the light emitting diode 3.

FIG. 4, FIG. 5, and FIG. 6 show the light emitting diode package 1 soldered onto two metal wires 200. The metal wire 200 can be a bare wire, or the exposed part of an enameled wire or a plastic coated wire. The two metal wires 200 are respectively soldered to the two mounting pads 2e. Through the first bonding wire 4, the second bonding wire 5, the chip bonding pad 2c, and the wire bonding pad 2d, electricity is provided to the LED chip 3 and the LED chip 3 illuminates. Usually the metal wire 200 is a copper wire, and wires made of the other metal having high conductivity are adoptable. However, shielded by the printed circuit board 2, the field angle of the light emitting diode package 1 cannot be larger than 180 degrees.

In addition, when soldering the light emitting diode package 1 onto the metal wires 200, solder paste is put onto the metal wire 200 first, and then the two mounting pads 2e are put onto the two metal wires 200. Next, the light emitting diode package and the metal wires 200 are moved to a reflow oven for reflow soldering. In the reflow soldering process, tin solder has good liquidity at high temperature. The light emitting diode package 1 might drift along with the flowing tin; as a result, soldering failure occurs. The soldering failure may cause an open-circuit, short-circuit, or an oblique mechanical arrangement of components. Rework is required for soldering failures and increases manufacturing costs including increasing labor costs and material costs.

### SUMMARY

In view of the above problem, this disclosure provides a light emitting diode package (LED lamp) having glue on two sides to solve the problems in the art.

This disclosure provides a light emitting diode package having glue on two sides including a metal frame, an LED chip and a transparent glue bulk. The metal frame includes a top surface and a bottom surface, and the metal frame further includes a first mounting pad and second mounting pad. A light transmission gap is defined between the first mounting pad and the second mounting pad. The light transmission gap provides communication of the top surface and the bottom surface, and causes the first mounting pad and the second mounting pad to be spaced apart from each other. The LED chip is mounted on the first mounting pad corresponding to the top surface. A first electrode and a second electrode of the LED chip are electrically connected to the first mounting pad and the second mounting pad respectively. The transparent glue bulk covers the top (first) surface and the bottom (second surface), wraps around the LED chip, and fills the light transmission gap. Outer edges of the first mounting pad and the second mounting pad are exposed from the transparent glue bulk.

In at least one embodiment, the light emitting diode package having glue on two sides further includes a first bonding wire and a second bonding wire, wherein the first bonding wire is connected to the first electrode and the first mounting pad, and the second bonding wire is connected to the second electrode and the second mounting pad.

In at least one embodiment, the transparent glue bulk includes an upper molded glue bulk and a lower molded glue bulk respectively combined with the top surface and the bottom surface.

In at least one embodiment, the upper molded glue bulk and the lower molded glue bulk are combined with each other via the light transmission gap, and the upper molded glue bulk wraps the light emitting diode, the first bonding wire, and the second bonding wire.

In at least one embodiment, The light emitting diode package having glue on two sides further includes two metal wires; wherein portions, of the first mounting pad and the second mounting pad, exposed from the transparent glue bulk and corresponding the bottom surface are respectively soldered to the two metal wires.

In at least one embodiment, the lower molded glue bulk is located between the two metal wires.

In an embodiment of this disclosure, the transparent glue bulk is configured to limit the movement of the two metal wires. Namely, even if the metal wires drift due to the melted solder paste during reflow soldering, the two metal wires just clamp the transparent glue bulk, and connections between the metals wires and the mounting pads remain. Good soldering maintains product quality and production yield, and reduces manufacturing cost including labor cost and material cost.

### BRIEF DESCRIPTION OF THE DRAWINGS

The present invention will become more fully understood from the detailed description given herein below for illustration only, and thus not limitative of the present invention, wherein:

FIG. 1 is a front view of a light emitting diode package known in the prior art;

FIG. 2 is a top view of a light emitting diode package, as known in the prior art;

FIG. 3 is a bottom view of a light emitting diode package, as known in the prior art;

FIG. 4 is a front view of a light emitting diode package soldered onto two metal wires, as known in the prior art;

FIG. 5 is a top view of a light emitting diode package soldered onto two metal wires, as known in the prior art;

FIG. 6 is a front view of a light emitting diode package welded onto two metal wires, as known in the prior art;

FIG. 7 is a front view of a light emitting diode package according to an embodiment of this disclosure;

FIG. 8 is a top view of a light emitting diode package according to an embodiment of this disclosure;

FIG. 9 is a bottom view of a light emitting diode package according to an embodiment of this disclosure;

FIG. 10 is a front view of a light emitting diode package soldered onto two metal wires according to an embodiment of this disclosure;

FIG. 11 is a top view of a light emitting diode package soldered onto two metal wires according to an embodiment of this disclosure; and

FIG. 12 is a bottom view of a light emitting diode package soldered onto two metal wires according to an embodiment of this disclosure.

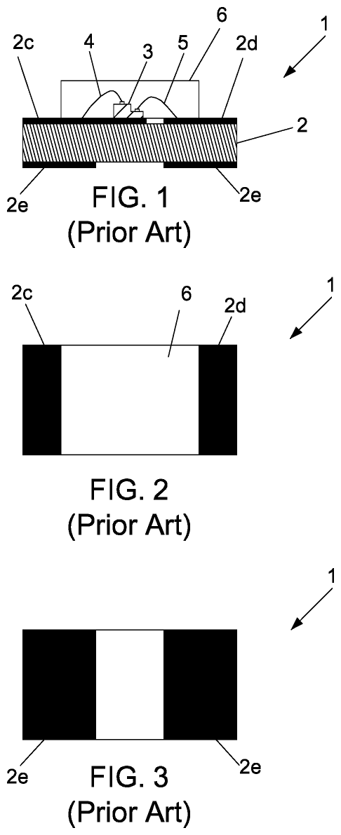

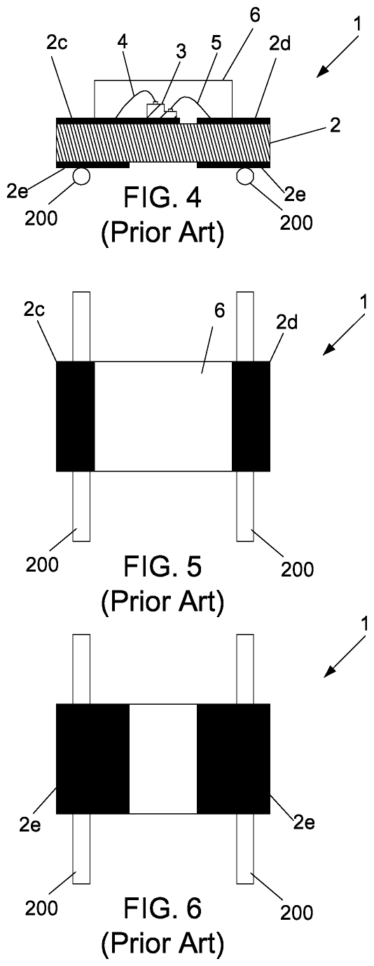

### DETAILED DESCRIPTION

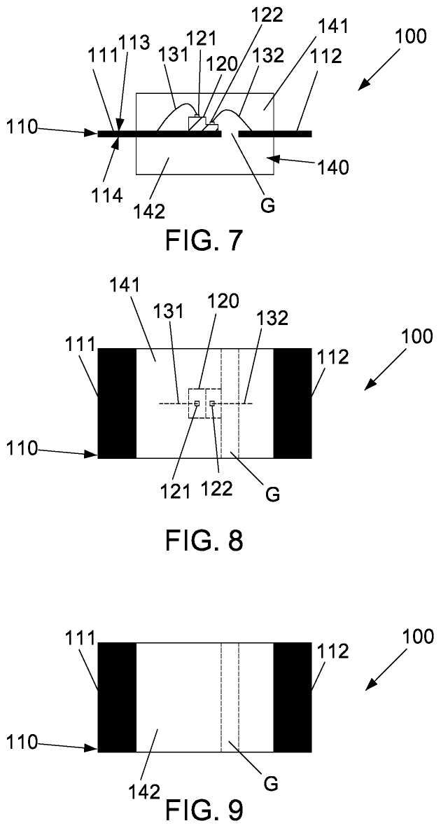

Referring to FIG. 7, FIG. 8, and FIG. 9, a light emitting diode package 100, also referred to as an LED lamp or LED lamp package, having glue on two sides according to an embodiment of this disclosure is shown. The light emitting diode package having glue on two sides 100 includes a metal frame 110, an LED chip 120, a first bonding wire 131, a second bonding wire 132, and a transparent glue bulk or material 140.

As shown in FIG. 7, FIG. 8, and FIG. 9, the metal frame 110 is made of metal, and has good electrical and thermal conductivities. The metal 110 includes a top surface 113 and a bottom surface 114. The metal frame 110 further includes a light transmission gap G, and the light transmission gap G communicates between the top surface 113 and the bottom surface 114. In particular, in this embodiment, the metal 110 includes a first mounting pad 111 and a second mounting pad 112. The light transmission gap G is defined between the first mounting pad 111 and the second mounting pad 112. The light transmission gap G communicates the top surface 113 and the bottom surface 114, and keeps the first mounting pad 111 and the second mounting pad 112 being spaced from each other.

As shown in FIG. 7, FIG. 8, and FIG. 9, the first mounting pad 111 provides a bonding position, and the bonding position corresponds to the top surface 113. The LED chip 120 is disposed at the bonding position, that is, the LED chip 120 is mounted on the first mounting pad 111, and corresponds to the top surface 113 of the metal frame 110. The LED chip 120 includes a first electrode 121 and a second electrode 122. As shown in FIG. 7, FIG. 8, and FIG. 9, the first bonding wire 131 is connected to the first electrode 121 and the first mounting pad 122, and the second bonding wire 132 is connected to the second electrode 122 and the second mounting pad 112. The first bonding wire 131 and the second bonding wire 132 electrically connect the LED chip 120 to the first mounting pad 111 and the second mounting pad 112.

As shown in FIG. 7, FIG. 8, and FIG. 9, the transparent glue material 140 covers the top (first) surface 113 and the bottom (second) surface 114, wraps around the LED chip 120, the first bonding wire 131 and the second bonding wire 132, and fills the light transmission gap G. Moreover, outer edges of the first mounting pad 111 and the second mounting pad 112 are exposed from the transparent glue bulk 140; namely, the two opposite edges of the metal frame 110 are exposed from the transparent glue bulk 140.

As shown in FIG. 7, the transparent glue bulk 140 includes an upper molded glue material 141 and a lower molded glue material 142, respectively combined with the top surface 113 and the bottom surface 114. The upper molded glue material 141 and the lower molded glue material 142 fill the light transmission gap G and are combined with each other via the light transmission gap G. In one example, the lower molded glue bulk 142 is combined with the bottom surface 114 at first to bind the first mounting 111 and the second mounting pad 112 into the metal frame 110, and then the LED chip is mounted and the bonding wires 131, 132 are bonded. Finally the upper molded glue material 141 is combined with the top surface 113 to wrap around and cover the LED chip 120, the first bonding wire 131 and the second bonding wire 132.

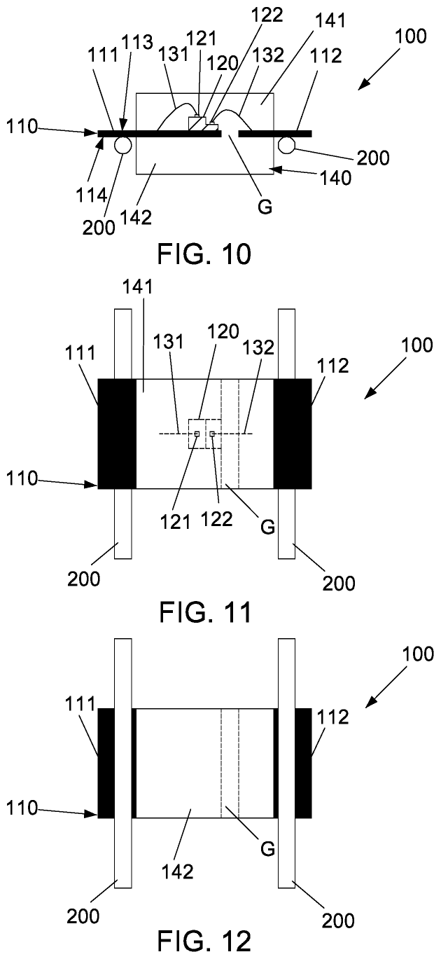

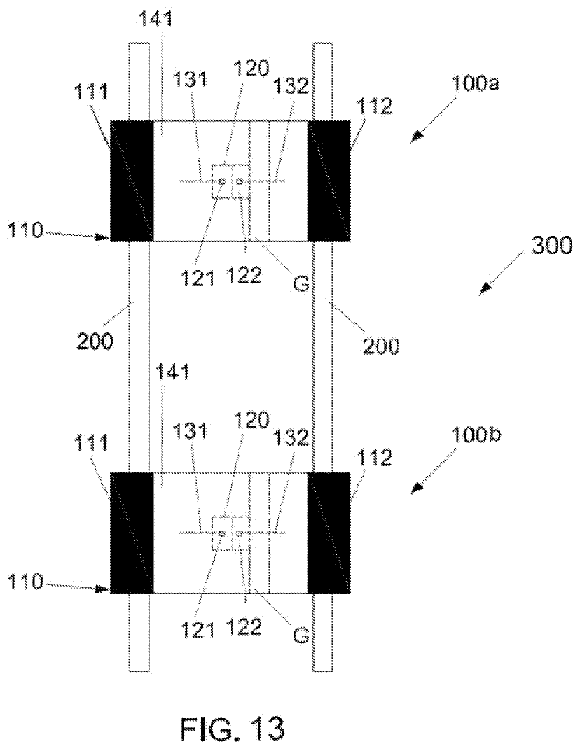

Referring to FIG. 10, FIG. 11, and FIG. 12, the light emitting diode package having glue on two sides 100 is provided to be soldered onto two metal wires 200. The metal wire 200 can be a bare wire, or the exposed part of an enameled wire or a plastic coated wire. Portions, of the first mounting pad 111 and the second mounting pad 112, exposed from the transparent glue bulk on bottom surface are respectively welded to the two metal wires 200. Through the first bonding wire 131, the second bonding wire 132, the first mounting pad 111, and the second mounting pad 112, electricity is provided to the LED chip 120 and the LED chip 120 illuminates. Usually the metal wire 200 is a copper wire, and wires made of the other metal having high conductivity are adoptable. Providing a plurality of light emitting diode packages 100 welded onto the two metal wires 200 in sequence, a light string that illuminates light in plural directions is obtained.

As shown in FIG. 7 to FIG. 12, Applying electricity to the first electrode 121 and the second electrode 122 via the two metal wires 200, the LED chip 120 illuminates. At the moment, the transparent glue material 140 serves as a light-guide, and light diverges upward on the top surface 113. Meanwhile, the transparent glue material 140 guides light to travel through the light transmission gap G, and to travel through the lower molded glue material 142. And finally, the light diverges downward. Therefore, in this disclosure, the light emitting diode package having transparent glue on two sides 100 illuminates light in 360 degrees and metal frame 110 has good thermal conductivity to dissipate heat from the LED chip 120. In addition, by coating or electroplating a reflecting layer on the surface of the metal frame 110, light absorbed by the surface of the metal frame 110 is prevented and luminance upward or downward is enhanced. Particles, such as fluorescent particles, reflective particles, or dye particles, can be added into the transparent glue bulk 140 to change illumination characteristics.

As shown in FIG. 10, observing in the front view of the light emitting diode package having glue on two sides 100, outer edges of the first mounting pad 111 and the second mounting pad 112 are exposed from the lower molded glue material 142, and L-shaped sections are formed between the lower molded glue material 142 and the mounting pads 111, 112. The two metal wires 200 are located in the L-shaped sections respectively, and are respectively welded to the first mounting pad 111 and the second mounting pad 112. Therefore, the lower molded glue bulk 142 is located between the two metal wires 200. The transparent glue bulk 142 limits the movement of the two metal wires 200. In other words, in this embodiment, even if the metal wires 200 drift due to the melted solder paste in the reflow soldering, the two metal wires just clamp the lower molded glue material 142, and connections between the metals wires 200 and the mounting pads 141, 142 remain. Good soldering maintains product quality and production yield, and reduces manufacturing cost including labor cost and material cost.

1.-6. (canceled)

7. A light string, comprising:
a first wire having a first plurality of exposed conductive portions,
a second wire aligned in parallel to the first wire and having a second plurality of exposed conductive portions,
a plurality of light-emitting diode (LED) lamps, each of the plurality of (LED) lamps including:
a metal frame, including a first mounting pad and a second mounting pad, each of the first mounting pad and the second mounting pad include a top surface and a bottom surface; wherein a light transmission gap is defined between the first mounting pad and the second mounting pad;
an LED chip mounted on the top surface of the first mounting pad; wherein a first electrode and a second electrode of the LED chip are electrically connected to the first mounting pad and the second mounting pad respectively; and
a transparent glue material covering portions of the top surfaces and the bottom surfaces of the first and second mounting pads, covering the LED chip, and filling the light transmission gap; wherein outer edges of the first mounting pad and the second mounting pad, and portions of the top and bottom surfaces are exposed outside of the transparent glue material, and wherein a bottom portion of the transparent glue material projects away from the bottom surfaces of the mounting pads, and the bottom portion of the transparent glue material is at least partially positioned between an exposed conductive portion of the first wire and an exposed conductive portion of the second wire so as to prevent contact between the exposed conductive portion of the first wire and the exposed conductive portion of the second wire during soldering of the metal frame to the first and second wires; and
wherein the first mounting pads of the plurality of LED lamps are connected to the first plurality of exposed conductive portions of the first wire, and the second mounting pads of the plurality of LED lamps are connected to the second plurality of exposed conductive portions of the second wire.

8. The light string of claim 7, wherein the top surface of the first mounting pad includes a reflective coating.

9. The light string of claim 7, wherein the transparent glue material forms a planar exterior top surface and a planar exterior bottom surface.

10. The light string of claim 7, wherein the light transmission gap defines a length and a width, the length being longer than the width, the width defined by a distance between the first mounting pad and the second mounting pad.

11. The light string of claim 10, wherein each first mounting pad of the plurality of LED lamps is soldered to one of the first plurality of exposed conductive portions of the first wire, and each second mounting pad of the plurality of LED lamps is soldered to one of the second plurality of exposed conductive portions of the second wire.

12. The light string of claim 7, wherein the transparent glue material defines an exterior side surface that is perpendicular to a bottom surface of the metal frame.

13. The light string of claim 12, wherein the exterior side surface and the bottom surface of the metal frame define a space therebetween, and a portion of the first wire is located in the space.

14.-20. (canceled)

21. A light emitting diode package having transparent material on two sides, comprising:
a metal frame, including a first mounting pad and a second mounting pad, each of the first mounting pad and the second mounting pad include a top surface and a bottom surface; wherein a light transmission gap is defined between the first mounting pad and the second mounting pad, the light transmission gap communicates between the top surface and the bottom surface and maintains spacing between the first mounting pad and the second mounting pad;
a light-emitting diode (LED) chip, the LED chip is mounted on the top surface of the first mounting pad; wherein a first electrode and a second electrode of the LED chip are electrically connected to the first mounting pad and the second mounting pad respectively; and
a transparent glue material covering portions of the top surfaces and the bottom surfaces of the first and second mounting pads, wrapping around the LED chip, and filling the light transmission gap; wherein outer edges of the first mounting pad and the second mounting pad are exposed outside of the transparent glue material; and
wherein a bottom portion of the transparent glue material projects away from the bottom surfaces of the mounting pads.

22. The light emitting diode package having glue on two sides according to claim 21, further comprising a first bonding wire and a second bonding wire, wherein the first bonding wire is connected to the first electrode and the first mounting pad, and the second bonding wire is connected to the second electrode and the second mounting pad.

23. The light emitting diode package having glue on two sides according to claim 22, wherein the transparent glue material includes an upper molded glue material and a lower molded glue material respectively combined with the top surface and the bottom surface.

24. The light emitting diode package having glue on two sides according to claim 23, wherein the upper molded glue material and the lower molded glue material are combined with each other via the light transmission gap, and the upper molded glue material wraps around the light emitting diode, the first bonding wire, and the second bonding wire.

25. The light emitting diode package having glue on two sides according to claim 24, further comprising two metal wires, wherein portions of the first mounting pad and the second mounting pad are exposed from the transparent glue material and corresponding bottom surfaces of the first and second mounting pads are respectively soldered to the two metal wires.

26. The light emitting diode package having glue on two sides according to claim 25, wherein the lower molded glue material is located between the two metal wires.

27. A light string, comprising:
a first plastic-coated wire,
a second plastic-coated wire arranged adjacent to the first plastic-coated wire;
a plurality of light-emitting diode (LED) lamps, each of the plurality of (LED) lamps including:
a frame, including a first portion and a second portion, the first portion having a top surface, a bottom surface, and an edge, each of the top and bottom surfaces having a length that is greater than a thickness of the edge, the second portion having a top surface and a bottom surface, and defining a light transmission gap between the first portion and the second portion;
an LED chip mounted on the top surface of the first portion of the frame and having a first electrode electrically connected to the first portion of the frame and a second electrode electrically connected to the second portion of the frame; and
a transparent material covering a portion of the first portion of the frame, including portions of the top and bottom surfaces of the first portion of the frame, covering a portion of the second portion of the frame, including top and bottom surfaces of the second portion of the frame, covering the LED chip, and filling the light transmission gap; wherein another portion of the first portion of the frame is not covered by the transparent material, and another portion of the second portion of the frame is not covered by the transparent material; and
wherein the first portion of the frame is connected to an exposed conductive portion of the first wire, and the second portion of the frame is connected to a an exposed conductive portion of the second wire; and
wherein a bottom portion of the transparent material projects away from the bottom surfaces of the first and second portions of the metal frame, and the bottom portion of the transparent glue material is at least partially positioned between the exposed conductive portions of the first and second wires so as to prevent contact between the exposed conductive portion of the first wire and the exposed conductive portion of the second wire during soldering of the metal frame to the first and second wires.

28. The light string of claim 27, wherein the transparent material forms a planar exterior top surface and a planar exterior bottom surface.

29. The light string of claim 27, wherein the light transmission gap defines a length and a width, the length being longer than the width, the width defined by a distance between the first portion of the frame and the second portion of the frame.

30. The light string of claim 29, wherein the length is equal to a length of an edge of the first portion of the frame covered by the transparent material.

31. The light string of claim 27, wherein each first portion of each of the frames of the plurality of LED lamps is soldered to the first wire, and each second portion of each of the frames of the plurality of LED lamps is soldered to the second wire, and the first wire is arranged in parallel to the second wire.

32. The light string of claim 27, wherein the transparent glue material defines an exterior side surface that is perpendicular to a bottom surface of the first frame portion.

33. The light string of claim 27, wherein the exterior side surface and the bottom surface of the first frame portion define a space therebetween, and a portion of the first wire is located in the space.
